(19) United States
(12) Patent Application Publication
(10) Pub. No.: US 2024/0203953 A1
(43) Pub. Date: Jun. 20, 2024

(54) METHODS, SYSTEMS, APPARATUSES, AND DEVICES FOR MIXING QUANTUM DOT LIGHTING

(71) Applicant: KORRUS, INC., LOS ANGELES, CA (US)

(72) Inventors: Paul Kenneth PICKARD, Los Angeles, CA (US); Sina AFSHARI, Los Angeles, CA (US); Raghuram L.V. PETLURI, Los Angeles, CA (US); Benjamin HARRISON, Los Angeles, CA (US)

(21) Appl. No.: 18/511,649

(22) Filed: Nov. 16, 2023

Related U.S. Application Data
(63) Continuation of application No. PCT/US22/29849, filed on May 18, 2022.
(60) Provisional application No. 63/189,789, filed on May 18, 2021.

(51) Int. Cl. H01L 25/075; H01L 33/50

(52) U.S. Cl. CPC H01L 25/0753; H01L 33/502; H01L 33/507

(57) ABSTRACT

A digital content display includes a backlight that includes a violet-light emitting LED having an approximately 425 nm centered wavelength and a long-blue emitting LED having an approximately 470 nm centered wavelength, a spectrum conversion material adapted to receive light from at least one of the violet-light emitting LED and the long-blue emitting LED and converting at least a portion of received lights into green light with a half-max bandwidth of less than 30 nm, a green sub-pixel color filter, a red sub-pixel color filter and a blue sub-pixel color filter.

### CROSS REFERENCE TO RELATED APPLICATIONS

This application claims the benefit of U.S. Provisional Patent Application 63/189,789, filed May 18, 2021, the entire disclosures of each of which are hereby incorporated herein by reference.

### FIELD OF THE INVENTION

Generally, the present disclosure relates to the field of color displays. More specifically, the present disclosure relates to methods, systems, apparatuses, and devices for the emission of desirable melanopic light.

### BACKGROUND OF THE INVENTION

There are several different color standards used to define the color gamut produced by a computer display or television. The standard Rec. 2020 has one of the largest color gamuts. Rec. 2020 can produce colors that Rec. 709 cannot, for example. The RGB primaries used by Rec. 2020 are equivalent to monochromatic light sources on the CIE 1931 spectral space. The wavelengths of the Rec. 2020 primary colors are 630 nm for the red primary color, 532 nm for the green primary color, and 467 nm for the blue primary color.

A number of human health concerns are present when operating a computer display or television using Rec. 2020. While Rec. 2020 produces a very large color pallet it does so by emitting 467 nm blue, which is in the middle of the melanopic response of the human eye. When a person is looking at the screen with significant 467 nm blue light it generally causes suppression of melatonin production in the person, which keeps the person alert or awake. This may be acceptable, or even desirable during the daytime hours, but when operating the screen at night can continue to suppress melatonin production leading to a poor night's sleep.

Therefore, there is a need for improved methods, systems, apparatuses and devices for providing light induced melatonin production that may overcome one or more of the above-mentioned problems and/or limitations.

### SUMMARY

This summary is provided to introduce a selection of concepts in a simplified form, that are further described below in the Detailed Description. This summary is not intended to identify key features or essential features of the claimed subject matter. Nor is this summary intended to be used to limit the claimed subject matter's scope.

Aspects of the present inventions relate to a computer screen, television or the like that replaces the 467 nm blue with an apparent blue providing substantially the same perceived colors while minimizing emission in the melanopic region, which is centered around 470 nm with a bell-shaped curve. In embodiments, the 467 nm blue is replaced with two separate colors: violet (e.g. between 380 nm and 435 nm) and long-blue (e.g. between 475 nm and 505 nm). When the light emitted at these two separate wavelengths is received by the human eye, the person interprets the colors as a combined color, which is blue.

Aspects of the present inventions relate to a backlit LCD computer screen or television that includes a light source that emits light in the violet and blue regions with a blue filter that transmits both the violet and blue. Alternatively, the blue filter is two separate filters, one for violet and one for blue. In embodiments, the blue and green filters have relatively narrow transmission bands to avoid substantial overlap in the blue-green region. Overlap in this area could cause green light to leak through the blue filter and blue light to leak through the green filter. This reduces the color saturation and leads to a smaller color gamut.

Aspects of the present invention relate to a backlighting system for a computer screen or television that emits violet light to pump a conversion material (e.g. quantum dots, phosphor) to generate light of a wavelength that passes through a pixel filter. The combination of the pixel filter and violet pumped emission creating a spectra that has substantially separated emission bands between blue and green and green and red.

In embodiments, quantum dot material is used to convert backlight emission into appropriate bandwidths of emission for display pixel emission. In embodiments, the quantum dot material may be in the form of a film or surface that is remote from the LED package. In embodiments, the quantum dot material may be in or on the LED package. Heat can deteriorate the quantum dot material so the display backlight structure may have a thermal management system to maintain the quantum dot material at an acceptable temperature (e.g. maintain a minimum separation from heat sources such as the LEDs, processors, and other electronics).

Aspects of the present inventions relate to backlighting systems for displays and emissive displays. The LEDs, conversion materials, and spectral characteristics of system disclosed herein may be implemented with LEDs, mini-LEDs, etc. backlighting an LCD array. The systems disclosed may be implemented with emissive semiconductors such as micro-LEDs or OLEDs.

In accordance with an exemplary and non-limiting embodiment, a digital content display comprises a backlight comprising a violet-light emitting LED having an approximately 425 nm centered wavelength and a long-blue emitting LED having an approximately 470 nm centered wavelength, a spectrum conversion material adapted to receive light from at least one of the violet-light emitting LED and the long-blue emitting LED and converting at least a portion of received lights into green light with a half-max bandwidth of less than 30 nm, a green sub-pixel color filter, a red sub-pixel color filter and a blue sub-pixel color filter.

In accordance with an exemplary and non-limiting embodiment, a method, comprises emitting a light from a backlight comprising a violet-light emitting LED having an approximately 425 nm centered wavelength and a long-blue emitting LED having an approximately 470 nm centered wavelength, receiving the light emitted from at least one of the violet-light emitting LED and the long-blue emitting LED, converting at least a portion of received light into green light with a half-max bandwidth of less than 30 nm and filtering the converted light with a green sub-pixel color filter, a red sub-pixel color filter and a blue sub-pixel color filter.

In accordance with an exemplary and non-limiting embodiment, a digital content display, comprises a backlight comprising a violet-light emitting LED having an approximately 425 nm centered wavelength and a long-blue emitting LED having an approximately 470 nm centered wavelength, a green sub-pixel color filter adapted to receive light from the backlight the green sub-pixel filter having a center and peak wavelength of approximately 560 nm with an 80% relative maximum transmission (T_{MAX}) between a wavelength range of approximately 520-530 nm and 570-580 nm, a 50% relative T_{MAX} between a wavelength range of approximately 510-520 nm and 575-585 nm, and a 10% relative T_{MAX} between a wavelength range of approximately 475-485 nm and 605-615 nm, and a rejection stop band at wavelengths less than approximately 465 nm and greater than 625 nm, a red sub-pixel color filter adapted to receive light from the backlight the red sub-pixel filter having a T_{MAX} greater than 95% between a wavelength range of approximately 600-780 nm, an average transmission percentage (T_{AVE}) of greater than 90% between a wavelength range of approximately 600-750 nm, a relative T_{MAX} of 80% between a wavelength range of approximately 595-605 nm, a relative T_{MAX} of 50% between a wavelength range of approximately 575-585 nm, a relative T_{MAX} of 10% between a wavelength range of approximately 565-577 nm and a rejection stop band at wavelengths less than approximately 565 nm; and a blue sub-pixel color filter adapted to receive light from the backlight the blue sub-pixel filter having a T_{MAX} greater than 95% between a wavelength range of approximately 380-460 nm, an average transmission percentage (T_{AVE}) of greater than 85% between a wavelength range of approximately 390-460 nm, a relative T_{MAX} of 80% between a wavelength range of approximately 460-470 nm, a relative T_{MAX} of 50% between a wavelength range of approximately 470-490 nm, a relative T_{MAX} of 10% between a wavelength range of approximately 500-510 nm and a rejection stop band at wavelengths greater than approximately 515 nm.

In accordance with an exemplary and non-limiting embodiment, a digital content display comprises a backlight comprising a violet-light emitting LED having an approximately 425 nm centered wavelength and a long-blue emitting LED having an approximately 470 nm centered wavelength, a spectrum conversion material adapted to receive light from at least one of the violet-light emitting LED and the long-blue emitting LED and converting at least a portion of received lights into green light with a half-max bandwidth of less than 20 nm, a green sub-pixel color filter adapted to receive and filter the converted light, a red sub-pixel color filter adapted to receive and filter the converted light and a blue sub-pixel color filter adapted to receive and filter the converted light.

### BRIEF DESCRIPTION OF THE DRAWINGS

The accompanying drawings, which are incorporated in and constitute a part of this disclosure, illustrate various embodiments of the present disclosure. The drawings contain representations of various trademarks and copyrights owned by the Applicants. In addition, the drawings may contain other marks owned by third parties and are being used for illustrative purposes only. All rights to various trademarks and copyrights represented herein, except those belonging to their respective owners, are vested in and the property of the applicants. The applicants retain and reserve all rights in their trademarks and copyrights included herein, and grant permission to reproduce the material only in connection with reproduction of the granted patent and for no other purpose.

Furthermore, the drawings may contain text or captions that may explain certain embodiments of the present disclosure. This text is included for illustrative, non-limiting, explanatory purposes of certain embodiments detailed in the present disclosure.

FIG. 1 is an illustration of a backlight spectrum for a lighting system in accordance with exemplary and non-limiting embodiments.

FIG. 2 is an illustration of a filtered backlit spectrum in accordance with exemplary and non-limiting embodiments.

FIG. 3 is an illustration of a display gamut in accordance with exemplary and non-limiting embodiments.

FIG. 4 is an illustration of a backlight spectrum for a lighting system in accordance with exemplary and non-limiting embodiments.

FIG. 5 is an illustration of a filtered backlight spectrum for a lighting system in accordance with exemplary and non-limiting embodiments.

FIG. 6 is an illustration of a display gamut in accordance with exemplary and non-limiting embodiments.

FIG. 7 is an illustration of a display gamut in accordance with exemplary and non-limiting embodiments.

FIGS. 8A-8B are an illustration of a display system in accordance with exemplary and non-limiting embodiments.

FIG. 9 is an illustration of exemplary and non-limiting filter characteristics.

### DETAIL DESCRIPTIONS OF THE INVENTION

As a preliminary matter, it will readily be understood by one having ordinary skill in the relevant art that the present disclosure has broad utility and application. As should be understood, any embodiment may incorporate only one or a plurality of the above-disclosed aspects of the disclosure and may further incorporate only one or a plurality of the above-disclosed features. Furthermore, any embodiment discussed and identified as being “preferred” is considered to be part of a best mode contemplated for carrying out the embodiments of the present disclosure. Other embodiments also may be discussed for additional illustrative purposes in providing a full and enabling disclosure. Moreover, many embodiments, such as adaptations, variations, modifications, and equivalent arrangements, will be implicitly disclosed by the embodiments described herein and fall within the scope of the present disclosure.

Accordingly, while embodiments are described herein in detail in relation to one or more embodiments, it is to be understood that this disclosure is illustrative and exemplary of the present disclosure, and are made merely for the purposes of providing a full and enabling disclosure. The detailed disclosure herein of one or more embodiments is not intended, nor is to be construed, to limit the scope of patent protection afforded in any claim of a patent issuing here from, which scope is to be defined by the claims and the equivalents thereof. It is not intended that the scope of patent protection be defined by reading into any claim a limitation found herein that does not explicitly appear in the claim itself.

Thus, for example, any sequence(s) and/or temporal order of steps of various processes or methods that are described herein are illustrative and not restrictive. Accordingly, it should be understood that, although steps of various processes or methods may be shown and described as being in a sequence or temporal order, the steps of any such processes or methods are not limited to being carried out in any particular sequence or order, absent an indication otherwise. Indeed, the steps in such processes or methods generally may be carried out in various different sequences and orders while still falling within the scope of the present invention. Accordingly, it is intended that the scope of patent protection is to be defined by the issued claim(s) rather than the description set forth herein.

Additionally, it is important to note that each term used herein refers to that which an ordinary artisan would understand such term to mean based on the contextual use of such term herein. To the extent that the meaning of a term used herein-as understood by the ordinary artisan based on the contextual use of such term-differs in any way from any particular dictionary definition of such term, it is intended that the meaning of the term as understood by the ordinary artisan should prevail.

Furthermore, it is important to note that, as used herein, “a” and “an” each generally denotes “at least one,” but does not exclude a plurality unless the contextual use dictates otherwise. When used herein to join a list of items, “or” denotes “at least one of the items,” but does not exclude a plurality of items of the list. Finally, when used herein to join a list of items, “and” denotes “all of the items of the list.”

The following detailed description refers to the accompanying drawings. Wherever possible, the same reference numbers are used in the drawings and the following description to refer to the same or similar elements. While many embodiments of the disclosure may be described, modifications, adaptations, and other implementations are possible. For example, substitutions, additions, or modifications may be made to the elements illustrated in the drawings, and the methods described herein may be modified by substituting, reordering, or adding stages to the disclosed methods. Accordingly, the following detailed description does not limit the disclosure. Instead, the proper scope of the disclosure is defined by the appended claims. The present disclosure contains headers. It should be understood that these headers are used as references and are not to be construed as limiting upon the subjected matter disclosed under the header.

The present disclosure includes many aspects and features. Moreover, while many aspects and features relate to, and are described in the context of facilitating provisioning of a virtual experience, embodiments of the present disclosure are not limited to use only in this context.

A mini-LED configuration may include one or more backlighting systems where the mini-LED module(s) is configured with solid state lighting systems as described herein (e.g., a mini-LED module may have 10,000 solid state emitters and some of the emitters are configured to generate violet and long-blue light). If there is more than one LED backlight module, they may be separately controllable for segmented backlighting. Segmented backlighting may also be accomplished through control of the individual or groups of semiconductor lighting devices within a module.

In accordance with exemplary and non-limiting embodiments, a quantum dot material layer is provided either before or after the LCD layer in a backlit design. In embodiments, colored filters for each sub-pixel color (e.g., red, green and blue) may be provided to further refine the pixel emission spectra and/or to select which color from a set of colors is transmitted. In embodiments, filters may not be used because the backlight spectrum may not need refinement or selection. For example, if the quantum dot layer is before the LCD (on the side with the backlight) all converted colors may be present and a sub-pixel filter may be used to select and/or refine the appropriate color to transmit. If the quantum dot layer is after the LCD (on the opposite side of the backlight side) it may be patterned in such a way as to have separate red, green and blue quantum dot layers on the separate sub-pixels, which would not require filters for the selection because each sub-pixel would be generating emission of the correct color; although a filter may be used if refinement of the spectra is desired.

### Low EML Channel

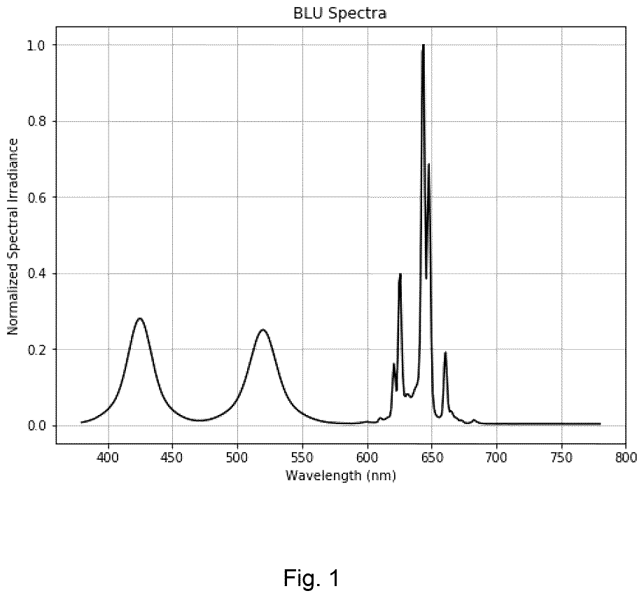

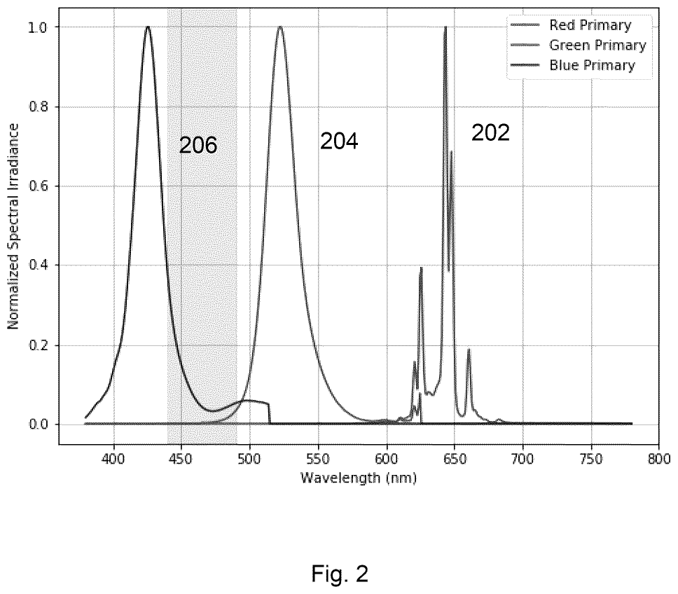

With reference to FIG. 1, there is illustrated a backlight spectrum for the lighting system, before it is filtered by the pixel filters, when a ˜425 nm violet LED is used to pump a conversion material in accordance with the principles of the present invention. The violet pump may be used to pump three different conversion materials (e.g., quantum dots, phosphor) to generate the blue, green and red spectrums illustrated in FIG. 2. Each of the red, green and blue converted emissions are relatively narrow (e.g., half-max width of the blue and green of ˜25 nm, red with a single peak with a half-max width of ˜25 nm (not shown)) with little overlap between them. A quantum dot conversion material may be used to generate each converted color or a subset of the colors. For example, the blue and green emissions may be a result of quantum dot conversion and the red emission may be phosphor converted.

With reference to FIG. 2, there is illustrated a filtered backlit spectrum when a ˜425 nm pump is used in accordance with the principles of the present invention. In other words, the lighting system emission spectrum of FIG. 1 is used to backlight an LCD display that includes red, green and blue sub-pixel filters producing, respectively, red primary spectrum 202, green primary spectrum 204 and blue primary spectrum 206. The filters generally decrease the overall intensity, but the width of the separate emissions is generally full in the desired wavelength bands while preserving substantial separation between the separate emissions. For example, with this filtered violet pumped conversion emission the energy in the melanopic activation region is very low, which can provide a good evening or night solution because it should not suppress the user's melatonin production.

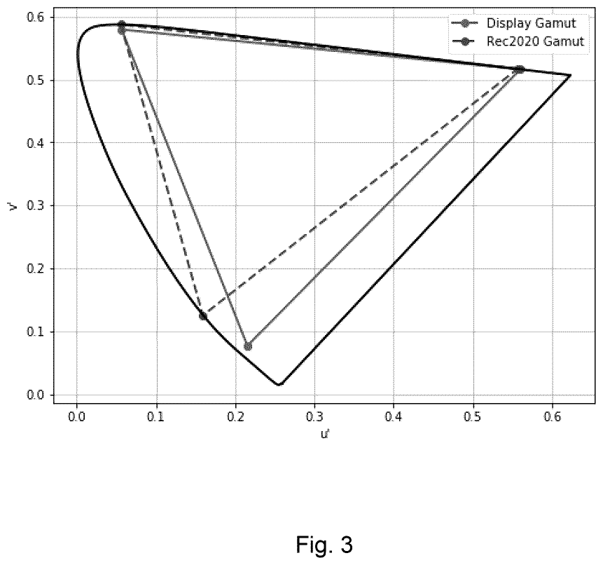

With reference to FIG. 3, there is illustrated the filtered spectrum results in the display gamut. FIG. 3 further illustrates the gamut specification in accordance with the Rec. 2020 standard. As can be seen, the resulting display emission substantially covers the Rec. 2020 specified gamut, while also substantially decreasing the emission energy in the melanopic activation region.

### High EML Channel

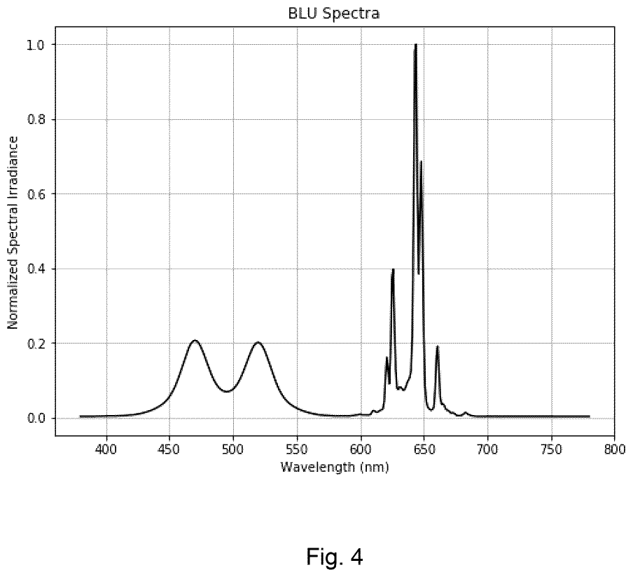

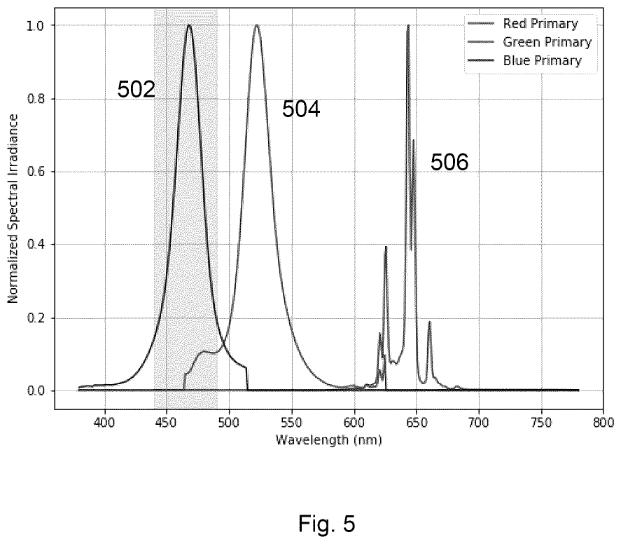

With reference to FIG. 4, there is illustrated a backlight spectrum for the lighting system, before it is filtered by the pixel filters, when a ˜470 nm cyan LED is used to pump a conversion material in accordance with the principles of the present invention. The long blue pump may be used to pump three different conversion materials (e.g. quantum dots, phosphor) to generate the blue, green and red spectrums illustrated in FIG. 5. Each of the red, green and blue converted emissions are relatively narrow (e.g. half-max width of the blue and green of ˜25 nm, red with a single peak with a half-max width of ˜25 nm (not shown)). A quantum dot conversion material may be used to generate each converted color or a subset of the colors. For example, the blue and green emissions may be a result of quantum dot conversion and the red emission may be phosphor converted.

With reference to FIG. 5, there is illustrated a filtered backlit spectrum when a 470 pump is used in accordance with the principles of the present invention. In other words, the lighting system emission spectrum of FIG. 4 is used to backlight an LCD display that includes red, green and blue sub-pixel filters producing red primary spectrum 506, green primary spectrum 504 and blue primary spectrum 503. The filters generally decrease the overall intensity, but the width of the separate emissions is generally full in the desired wavelength. This spectra produces relatively high energy in the melanopic activation region and may be useful during daytime use because the energy in the melanopic region may suppress the melatonin production of a user so they maintain alertness.

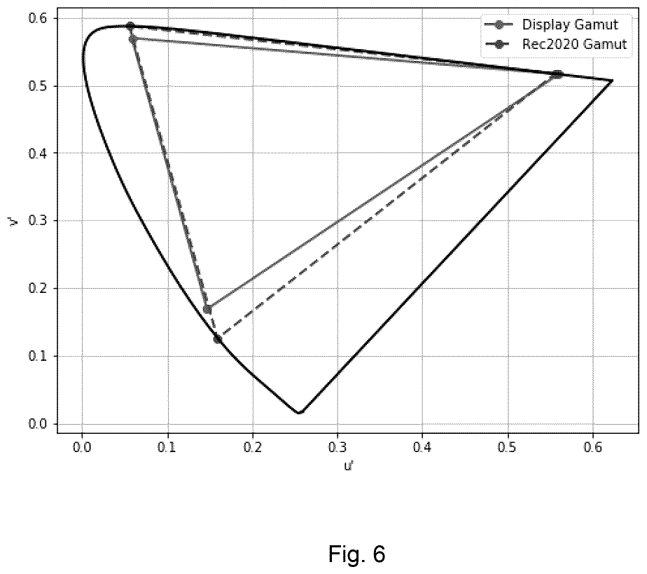

The filtered spectrum results in the display gamut illustrated in FIG. 6. FIG. 6 also illustrates the gamut specification in accordance with the Rec. 2020 standard. As can be seen, the resulting display emission substantially covers the Rec. 2020 specified gamut, while also substantially increasing the emission energy in the melanopic activation region.

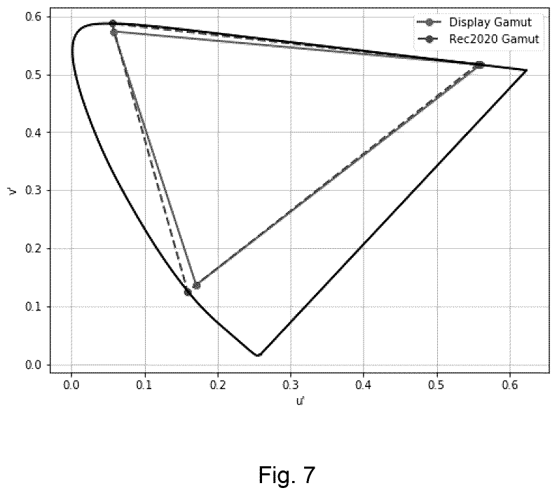

A computer display or television according to the principles of the present invention may operate with a fixed spectral backlight (e.g. a low melatonin energy spectrum, a high melatonin energy spectrum) or it may operate with alternative spectra, or channels, (e.g. the backlight is arranged to produce both low and high melatonin energy spectrum alternatively, selectably, etc.). In embodiments, the computer display or television may operate in a mode where both high and low melanopic energy are on simultaneously or in rapid succession to cause the user to perceive colors made from the two spectra. One advantage to operating the display with both spectra simultaneously is that the display gamut is expanded. FIG. 7 illustrates an exemplary and non-limiting display gamut when both high and low melanopic spectra as described in connection with FIGS. 1-6 are activated. As can be seen, with both channels on, the Rec. 2020 standard gamut is nearly replicated. This display may produce relatively high melanopic energy.

Metrics for the low, high and simultaneous high and low backlighting system are described below:

Violet-Pumped Display:
Melanopic Ratio: 1.05
Blue Percentage (radiometric power between 440 nm and 490 nm): 5.2%
sRGB Coverage: 99.3%
DCIP3 Coverage: 97.7%
Rec2020 Coverage: 90.6%

Cyan-Pumped Display:
Melanopic Ratio: 1.46
Blue Percentage (radiometric power between 440 nm and 490 nm): 23.3%
SRGB Coverage: 97.9%
DCIP3 Coverage: 93.6%
Rec2020 Coverage: 87.0%

Mixed Backlight with Maximum Gamut:
Melanopic Ratio: 1.31
Blue Percentage (radiometric power between 440 nm and 490 nm): 16.8%
sRGB Coverage: 100%
DCIP3 Coverage: 97.2%
Rec2020 Coverage: 94.3%

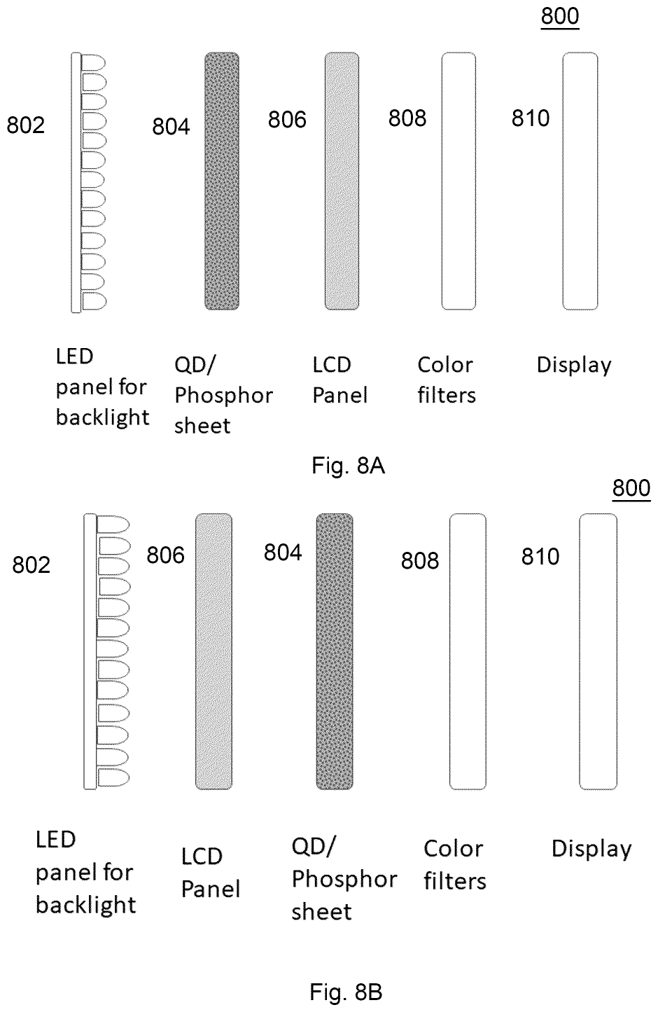

With reference to FIGS. 8A-8B, there are illustrated exemplary and non-limiting embodiments of a display system 800. With reference to FIG. 8A, light is emitted from the LED panel 802 forming a backlight from left to right onto quantum dot/phosphor sheet 804. Light emitted from the quantum dot/phosphor sheet 804 next passes through LCD panel 806 and through color filters 808 before forming display 810. Note that, with reference to FIG. 8B, light emitted from LED panel 802 pay next pass through LCD panel 806 before passing through quantum dot/phosphor sheet 804.

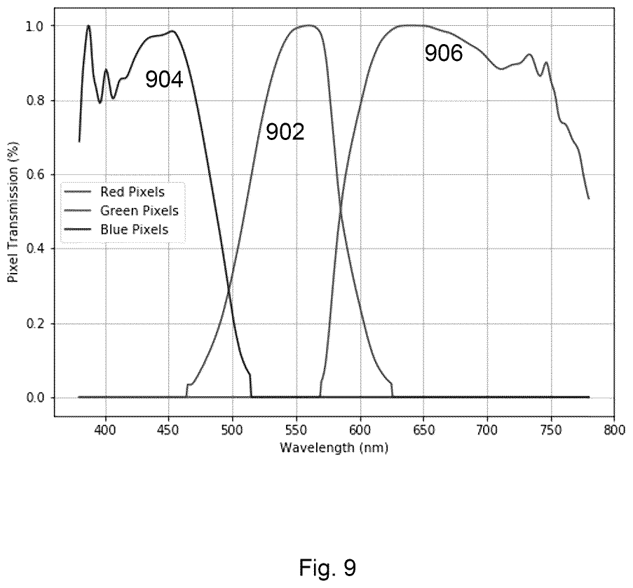

With reference to FIG. 9, there is illustrated an exemplary and non-limiting embodiment of the pixel transmission characteristics of the green filter 902, the blue filter 904 and the red filter 906. Blue filter 904 may be a shortwave pass filter which may be either a dielectric thin film deposited filter or a color glass filter or both with the following properties (where T=percentage transmission):

In wavelength region 380-460 nm:
T_{Max}>95%
T_{Ave}>85%
Tₘᵢₙ>70%

Further in wavelength region 390-460 nm:
T_{Ave}>85% (preferably >90%)
Tₘᵢₙ>80%

80% relative T_{Max} in wavelength region 460-470 nm

50% relative T_{Max} in wavelength region 470-490 nm

10% relative T_{Max} in wavelength region 500 (+/−5 nm)-510 nm

Rejection Stop band (no transmission) in wavelengths >515 nm (+/−5 nm).

Green filter 902 may be a bandpass filter which may be either a dielectric thin film deposited filter or a color glass filter or both with the following properties (where T=percentage transmission):
Center and Peak wavelength 560+/−5 nm
Peak T>95%
Tₘₐₓ>95%
FWHM=50+/−5 nm
80% relative Tₘₐₓ
   in short wavelength(SW80%) 520-530 nm
   in long wavelength(LW80%) 570-580 nm
50% relative Tₘₐₓ
   in short wavelength(SW80%) 510-520 nm
   in long wavelength(LW80%) 575-585 nm
10% relative Tₘₐₓ
   in short wavelength(SW80%) 475-485 nm
   in long wavelength(LW80%) 605-615 nm
Rejection Stop band (no transmission)
   in wavelengths<465 nm (+/−5 nm)
in wavelengths>625 nm (+/−5 nm)

Red filter 906 may be a longwave pass filter which may be either a dielectric thin film deposited filter or a color glass filter or both with the following properties (where T=percentage transmission):

In wavelength region 600-780 nm:
T_{Max}>95%
T_{Ave}>80%
Tₘᵢₙ>50%

Further in wavelength region 600-750 nm
T_{Ave}>85% (preferably >90%)
Tₘᵢₙ>80%

80% relative T_{Max} in 595-605 nm

50% relative T_{Max} in 575-585 nm

10% relative T_{Max} in 565-577 nm

Rejection Stop band (no transmission) in wavelengths <565 nm (+/−5 nm)

Generally, consistent with embodiments of the disclosure, program modules may include routines, programs, components, data structures, and other types of structures that may perform particular tasks or that may implement particular abstract data types. Moreover, embodiments of the disclosure may be practiced with other computer system configurations, including hand-held devices, general purpose graphics processor-based systems, multiprocessor systems, microprocessor-based or programmable consumer electronics, application specific integrated circuit-based electronics, minicomputers, mainframe computers, and the like. Embodiments of the disclosure may also be practiced in distributed computing environments where tasks are performed by remote processing devices that are linked through a communications network. In a distributed computing environment, program modules may be located in both local and remote memory storage devices.

Furthermore, embodiments of the disclosure may be practiced in an electrical circuit comprising discrete electronic elements, packaged or integrated electronic chips containing logic gates, a circuit utilizing a microprocessor, or on a single chip containing electronic elements or microprocessors. Embodiments of the disclosure may also be practiced using other technologies capable of performing logical operations such as, for example, AND, OR, and NOT, including but not limited to mechanical, optical, fluidic, and quantum technologies. In addition, embodiments of the disclosure may be practiced within a general-purpose computer or in any other circuits or systems.

Embodiments of the disclosure, for example, may be implemented as a computer process (method), a computing system, or as an article of manufacture, such as a computer program product or computer readable media. The computer program product may be a computer storage media readable by a computer system and encoding a computer program of instructions for executing a computer process. The computer program product may also be a propagated signal on a carrier readable by a computing system and encoding a computer program of instructions for executing a computer process. Accordingly, the present disclosure may be embodied in hardware and/or in software (including firmware, resident software, micro-code, etc.). In other words, embodiments of the present disclosure may take the form of a computer program product on a computer-usable or computer-readable storage medium having computer-usable or computer-readable program code embodied in the medium for use by or in connection with an instruction execution system. A computer-usable or computer-readable medium may be any medium that can contain, store, communicate, propagate, or transport the program for use by or in connection with the instruction execution system, apparatus, or device.

The computer-usable or computer-readable medium may be, for example but not limited to, an electronic, magnetic, optical, electromagnetic, infrared, or semiconductor system, apparatus, device, or propagation medium. More specific computer-readable medium examples (a non-exhaustive list), the computer-readable medium may include the following: an electrical connection having one or more wires, a portable computer diskette, a random-access memory (RAM), a read-only memory (ROM), an erasable programmable read-only memory (EPROM or Flash memory), an optical fiber, and a portable compact disc read-only memory (CD-ROM). Note that the computer-usable or computer-readable medium could even be paper or another suitable medium upon which the program is printed, as the program can be electronically captured, via, for instance, optical scanning of the paper or other medium, then compiled, interpreted, or otherwise processed in a suitable manner, if necessary, and then stored in a computer memory.

Embodiments of the present disclosure, for example, are described above with reference to block diagrams and/or operational illustrations of methods, systems, and computer program products according to embodiments of the disclosure. The functions/acts noted in the blocks may occur out of the order as shown in any flowchart. For example, two blocks shown in succession may in fact be executed substantially concurrently or the blocks may sometimes be executed in the reverse order, depending upon the functionality/acts involved.

While certain embodiments of the disclosure have been described, other embodiments may exist. Furthermore, although embodiments of the present disclosure have been described as being associated with data stored in memory and other storage mediums, data can also be stored on or read from other types of computer-readable media, such as secondary storage devices, like hard disks, solid state storage (e.g., USB drive), or a CD-ROM, a carrier wave from the Internet, or other forms of RAM or ROM. Further, the disclosed methods' stages may be modified in any manner, including by reordering stages and/or inserting or deleting stages, without departing from the disclosure.

Although the invention has been explained in relation to its preferred embodiment, it is to be understood that many other possible modifications and variations can be made without departing from the spirit and scope of the invention.

What is claimed is:

1. A digital content display, comprising:
a backlight comprising a violet-light emitting LED having an approximately 425 nm centered wavelength and a long-blue emitting LED having an approximately 470 nm centered wavelength;
a spectrum conversion material adapted to receive light from at least one of the violet-light emitting LED and the long-blue emitting LED and converting at least a portion of received lights into green light with a half-max bandwidth of less than 30 nm;
a green sub-pixel color filter;
a red sub-pixel color filter; and
a blue sub-pixel color filter.

2. The digital content display of claim 1, wherein the spectrum conversion material comprises a quantum dot.

3. The digital content display of claim 1, wherein the spectrum conversion material comprises a phosphor.

4. The digital content display of claim 3, wherein the phosphor converts light from at least one of the violet-light emitting LED and the long-blue emitting LED into red light.

5. The digital content display of claim 4, wherein the red light is centered at a wavelength of approximately 645 nm.

6. The digital content display of claim 1, wherein the backlight is adapted to preferentially emit light from a single one of the violet-light emitting LED and the long blue emitting LED.

7. The digital content display of claim 6, wherein the preferential emission of light comprises a rapid alternating between light emitted from the violet-light emitting LED and the long blue emitting LED.

8. The digital content display of claim 1, wherein the backlight is adapted to preferentially emit a combined light comprising light from both violet-light emitting LED and the long blue emitting LED.

9. A method, comprising:
emitting a light from a backlight comprising a violet-light emitting LED having an approximately 425 nm centered wavelength and a long-blue emitting LED having an approximately 470 nm centered wavelength;
receiving the light emitted from at least one of the violet-light emitting LED and the long-blue emitting LED;
converting at least a portion of received light into green light with a half-max bandwidth of less than 30 nm; and
filtering the converted light with a green sub-pixel color filter, a red sub-pixel color filter and a blue sub-pixel color filter.

10. The method of claim 9, wherein the converting the portion of received light comprises passing the portion of received light through a quantum dot.

11. The method of claim 9, wherein the converting the portion of received light comprises passing the portion of received light through a phosphor.

12. The method of claim 11, wherein the phosphor converts light from at least one of the violet-light emitting LED and the long-blue emitting LED into red light.

13. The method of claim 12, wherein the red light is centered at a wavelength of approximately 645 nm.

14. The method of claim 9, wherein the backlight is adapted to preferentially emit light from a single one of the violet-light emitting LED and the long blue emitting LED.

15. The method of claim 14, wherein the preferential emission of light comprises a rapid alternating between light emitted from the violet-light emitting LED and the long blue emitting LED.

16. The method of claim 9, wherein the backlight is adapted to preferentially emit a combined light comprising light from both violet-light emitting LED and the long blue emitting LED.

17. A digital content display, comprising:
a backlight comprising a violet-light emitting LED having an approximately 425 nm centered wavelength and a long-blue emitting LED having an approximately 470 nm centered wavelength;
a green sub-pixel color filter adapted to receive light from the backlight the green sub-pixel filter having a center and peak wavelength of approximately 560 nm with an 80% relative maximum transmission (T_{MAX}) between a wavelength range of approximately 520-530 nm and 570-580 nm, a 50% relative T_{MAX} between a wavelength range of approximately 510-520 nm and 575-585 nm, and a 10% relative T_{MAX} between a wavelength range of approximately 475-485 nm and 605-615 nm, and a rejection stop band at wavelengths less than approximately 465 nm and greater than 625 nm;
a red sub-pixel color filter adapted to receive light from the backlight the red sub-pixel filter having a T_{MAX} greater than 95% between a wavelength range of approximately 600-780 nm, an average transmission percentage (T_{AVE}) of greater than 90% between a wavelength range of approximately 600-750 nm, a relative T_{MAX} of 80% between a wavelength range of approximately 595-605 nm, a relative T_{MAX} of 50% between a wavelength range of approximately 575-585 nm, a relative T_{MAX} of 10% between a wavelength range of approximately 565-577 nm and a rejection stop band at wavelengths less than approximately 565 nm; and
a blue sub-pixel color filter adapted to receive light from the backlight the blue sub-pixel filter having a T_{MAX} greater than 95% between a wavelength range of approximately 380-460 nm, an average transmission percentage (T_{AVE}) of greater than 85% between a wavelength range of approximately 390-460 nm, a relative T_{MAX} of 80% between a wavelength range of approximately 460-470 nm, a relative T_{MAX} of 50% between a wavelength range of approximately 470-490 nm, a relative T_{MAX} of 10% between a wavelength range of approximately 500-510 nm and a rejection stop band at wavelengths greater than approximately 515 nm.

18. A digital content display, comprising:
a backlight comprising a violet-light emitting LED having an approximately 425 nm centered wavelength and a long-blue emitting LED having an approximately 470 nm centered wavelength;
a spectrum conversion material adapted to receive light from at least one of the violet-light emitting LED and the long-blue emitting LED and converting at least a portion of received lights into green light with a half-max bandwidth of less than 20 nm;
a green sub-pixel color filter adapted to receive and filter the converted light;
a red sub-pixel color filter adapted to receive and filter the converted light; and
a blue sub-pixel color filter adapted to receive and filter the converted light.
